(19) United States
(12) Patent Application Publication
(10) Pub. No.: US 2023/0267309 A1
(43) Pub. Date: Aug. 24, 2023

(54) SYSTEMS AND METHODS FOR ENCODING/DECODING A DEEP NEURAL NETWORK

(71) Applicant: InterDigital VC Holdings France, SAS, Cesson-Sevigne (FR)

(72) Inventors: Shahab Hamidi-Rad, Sunnyvale, CA (US); Swayambhoo Jain, Milpitas, CA (US); Fabien Racape, San Francisco, CA (US)

(73) Assignee: InterDigital VC Holdings France, SAS, Cesson-Sevigne (FR)

(21) Appl. No.: 18/010,238

(22) PCT Filed: Jun. 9, 2021
(86) PCT No.: PCT/EP2021/065525

§ 371 Date: Dec. 14, 2022

Related U.S. Application Data
(60) Provisional application No. 63/041,044, filed on Jun. 18, 2020.

(51) Int. Cl. G06N 3/0455; G06N 3/0495

(52) U.S. Cl. CPC G06N 3/0455; G06N 3/0495

(57) ABSTRACT

The disclosure relates to a method comprising quantizing parameters of an input tensor, said quantizing using a codebook whose size is obtained according to a distortion value determined between the at least one tensor and a quantized version of said at least one tensor. The disclosure also relates to a method for quantizing parameters of the input tensor using a pdf-based initialization bounded according to at least one first pdf factor, said first pdf factor being selected among several candidate bounding pdf factors according to resulting entropy. The disclosure also relates to corresponding signal; bitstream, storage media and encoder and/or decoder devices.

The domain technical field of the one or more embodiments of the present disclosure is related to the technical domain of data processing, like for data compression and/or decompression. For instance, at least some embodiments relate to data compression/decompression involving large volume of data, like compression and/or decompression of at least a part of an audio and/or video stream, or like compression and/or decompression of data in link with Deep Learning techniques, like at least some parameters of a Deep Neural Network (DNN).

At least some embodiments relate to improving compression efficiency compared to existing video compression systems such as HEVC (HEVC refers to High Efficiency Video Coding, also known as H.265 and MPEG-H Part 2 described in “ITU-T H.265 Telecommunication standardization sector of ITU (10/2014), series H: audiovisual and multimedia systems, infrastructure of audiovisual services—coding of moving video, High efficiency video coding, Recommendation ITU-T H.265”), or compared to under development video compression systems such VVC (Versatile Video Coding, a new standard being developed by JVET, the Joint Video Experts Team).

To achieve high compression efficiency, image and video coding schemes usually employ prediction, including spatial and/or motion vector prediction, and transforms to leverage spatial and temporal redundancy in the video content. Generally, intra or inter prediction is used to exploit the intra or inter frame correlation, then the differences between the original image and the predicted image, often denoted as prediction errors or prediction residuals, are transformed, quantized, and entropy coded. To reconstruct the video, the compressed data are decoded by inverse processes corresponding to the entropy coding, quantization, transform, and prediction.

At least some embodiments relate to improving compression efficiency compared to existing systems for compression a Deep Neural Network (DNN). such as some compression standard or draft standard like the current upcoming standard ISO/MPEG7 of neural networks for multimedia content description and analysis current developed by the International Organization for Standardization.

Generally, in an encoding process, parameters of a DNN are quantized and entropy coded to obtain compressed data. To reconstruct data, the compressed data are decoded, the decoding processes including entropy decoding and inverse quantization.

### SUMMARY

The present principles enable at least one disadvantage of some known compression and/or decompression methods to be resolved by proposing a method comprising encoding data in at least one bitstream, data being one or more parameters of at least one tensor of at least one layer or sub-layer of at least one Deep Neural Network. It is to be pointed out that tensor of network parameters associated to a layer can include weights and/or biases or other kind of network parameters (as for tensors of “Batch Normalization” layer for instance).

According to an embodiment, a method for encoding at least one tensor associated to a layer of at least one Deep Neural Network in a bitstream is provided. Encoding the at least one tensor comprises obtaining a size of a codebook for quantizing parameters of said at least one tensor, said size being obtained according to a distortion value determined between the at least one tensor and a quantized version of said at least one tensor, quantizing said parameters using a codebook having said obtained size.

According to another embodiment, a device for encoding at least one tensor associated to a layer of at least one Deep Neural Network in a bitstream is provided, the device comprising at least one processor configured to obtain a size of a codebook for quantizing parameters of said at least one tensor, said size being obtained according to a distortion value determined between the at least one tensor and a quantized version of said at least one tensor, quantize said parameters using a codebook having said obtained size.

According to another embodiment, a method for decoding at least one tensor associated to a layer of at least one Deep Neural Network from a bitstream is provided, wherein decoding the at least one tensor comprises decoding from the bitstream an information representative of a type of a codebook, dequantizing parameters of said at least one tensor using the codebook.

According to another embodiment, an apparatus for decoding at least one tensor associated to a layer of at least one Deep Neural Network from a bitstream is provided, wherein the apparatus comprises at least one processor configured for decoding from the bitstream an information representative of a type of a codebook, dequantizing parameters of said at least one tensor using the codebook.

An aspect of the present disclosure relates to a device comprising at least one processor adapted for quantizing parameters of an input tensor, said quantizing using a pdf-based initialization bounded according to at least one first pdf factor, said first pdf factor being selected among several candidate bounding pdf factors according to resulting entropy.

An aspect of the present disclosure relates to a method comprising quantizing parameters of an input tensor, said quantizing using a pdf-based initialization bounded according to at least one first pdf factor, said first pdf factor being selected among several candidate bounding pdf factors according to resulting entropy.

According to some embodiments of the present disclosure, the quantizing uses a codebook-based quantization and wherein said code book size is obtained from several candidate codebook sizes according to errors between quantified tensors obtained from said input tensors by using said candidate codebook sizes and said input tensor.

According to another aspect, there is provided an apparatus. The apparatus comprises a processor. The processor can be configured to encode at least one tensor of at least one layer of at least one Deep Neural Network in at least one bitstream, and/or to decode a bitstream representative of at least one tensor of at least one layer of at least one Deep Neural Network, by executing any of the aforementioned methods.

According to another general aspect of at least one embodiment, there is provided a device comprising an apparatus according to any of the decoding embodiments; and at least one of (i) an antenna configured to receive a signal, the signal including the input data, (ii) a band limiter configured to limit the received signal to a band of frequencies that includes the input data, or (iii) a display configured to display an output representative of a video block.

According to another general aspect of at least one embodiment, there is provided a non-transitory computer readable medium containing data content generated according to any of the described encoding embodiments or variants.

According to another general aspect of at least one embodiment, there is provided a signal comprising data representative of at least one tensor of at least one layer or sub-layer of at least one Deep Neural Network, generated according to any of the described encoding embodiments or variants.

According to another general aspect of at least one embodiment, a bitstream is formatted to include data content generated according to any of the described encoding embodiments or variants.

According to another general aspect of at least one embodiment, there is provided a computer program product comprising instructions which, when the program is executed by a computer, cause the computer to carry out any of the described decoding embodiments or variants.

According to another general aspect of at least one embodiment, there is provided a non-transitory program storage device, readable by a computer, tangibly embodying a program of instructions executable by the computer to perform at least one of the methods of the present disclosure in any of its embodiments.

According to another general aspect of at least one embodiment, there is provided a computer readable storage medium comprising instructions which when executed by a computer cause the computer to carry out at least one of the methods of the present disclosure in any of its embodiments.

While not explicitly described, the devices of the present disclosure can be adapted to perform the methods of the present disclosure in any of theirs embodiments.

While not explicitly described, the present embodiments related to the methods or to the corresponding signal, devices, and computer readable storage media can be employed in any combination or sub-combination.

### BRIEF DESCRIPTION OF THE DRAWINGS

FIG. 1 shows a generic, standard encoding scheme.

FIG. 2 shows a generic, standard decoding scheme.

FIG. 3 shows a typical processor arrangement in which the described embodiments may be implemented;

FIG. 4 illustrates a DNN encoding scheme using at least some embodiment of the encoding method of the present disclosure; and

FIG. 5 illustrates a DNN decoding scheme using at least some embodiment of the decoding method of the present disclosure.

FIG. 6 illustrates an example of a method for quantizing parameters of a tensor of a layer of DNN according to an embodiment.

FIG. 7 illustrates an example of a method for quantizing parameters of a tensor of a layer of DNN according to another embodiment.

FIG. 8 illustrates an example of a method for encoding a DNN according to an embodiment.

FIG. 9 illustrates an example of a method for decoding a DNN according to an embodiment

FIG. 10 illustrates an example of a part of a bitstream comprising data representative of a tensor of at least one layer of a Deep Neural Network generated according to an embodiment.

It is to be noted that the drawings illustrate example embodiments and that the embodiments of the present disclosure are not limited to the illustrated embodiments.

### DETAILED DESCRIPTION

Many technical fields can involve the processing, with computer means, of large volume of data. Such processing can involve data compression and/or decompression of data, for a purpose a storage or of transmission of at least a part of such data for instance. Examples of compression and/or decompression of streams containing large amount of data can be found in the technical field of video processing, or in technical fields involving Deep Learning techniques.

Embodiments of the present disclosure are detailed hereinafter in link with Deep Neural Networks (DNNs) as an exemplary and not limitative purpose. It is clear however that the present disclosure can also apply to the compression/decompression of other large amount of data, like in the technical field of video processing. For instance, the present disclosure can apply to the compression/decompression of a tensor obtained by a Deep Learning Algorithm from at least one image.

Deep Neural Networks (DNNs) have shown state of the art performance in variety of domains such as multimedia processing, computer vision, speech recognition, natural language processing, etc. This performance however can come at the cost of massive computational cost as DNNs tend to have a huge number of parameters often running into millions, and sometimes even billions.

This can lead for instance to prohibitively high inference complexity. In simple words, inference is the deployment of a DNN, once trained, for processing input data, in view of their classification for instance. Inference complexity can be defined as the computational cost of applying trained DNN to input data for inference.

This high inference complexity can thus be an important challenge for using DNNs in environments involving an electronic device with limited hardware and/or software resource, for instance mobile or embedded devices with resource limitations like battery size, limited computational power, and memory capacity etc.

Deep Neural Networks are made up of several layers. A layer is associated with a set of parameters that can be obtained for instance during a training of the DNN. These parameters (like Weights and/or Biases) are stored as multi-dimensional arrays (also referred to herein as “tensors”). In the following, for simplicity purpose, the term “matrix can sometimes be used to denote a set of parameters (e.g. parameters of tensor of a given layer). It is to be understood, however, that some embodiments of the methods of the present disclosure can also be applied to tensors of parameters with more than two dimensions, such as 2D convolutional layers which usually contain 4D tensors of parameters. The huge number of parameters of DNNs can require a large bandwidth for deployment of DNNs (or solutions including DNNs) in distributed environments.

At least some embodiments of the present disclosure apply to the compression and/or decompression (decoding) of at least some parameters of at least one DNN (for instance a pre-trained DNN). Indeed, compression can facilitate the transmission and/or storage of the parameters of the at least one DNN. More precisely, at least some embodiments of the present disclosure apply to the compression of parameters of at least one tensor associated with at least one layer of at least one Deep Neural Network. The network parameters can be compressed one tensor at a time for instance.

Depending upon embodiments of the present disclosure, the layers (or sub-layers) can be of different types. For instance, in some embodiments, all the at least one layer can be convolutional layer(s), or fully connecter layer(s), or the at least one layer can comprise at least one convolutional layer and/or at least one fully connecter layer.

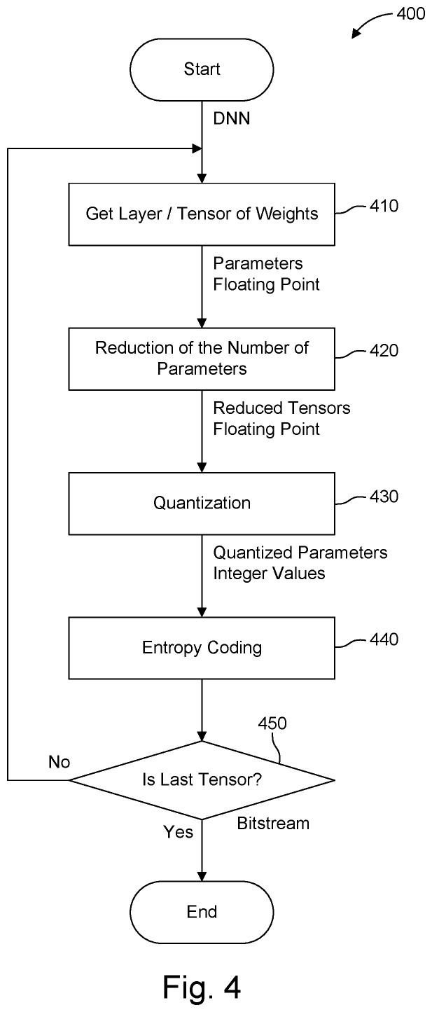

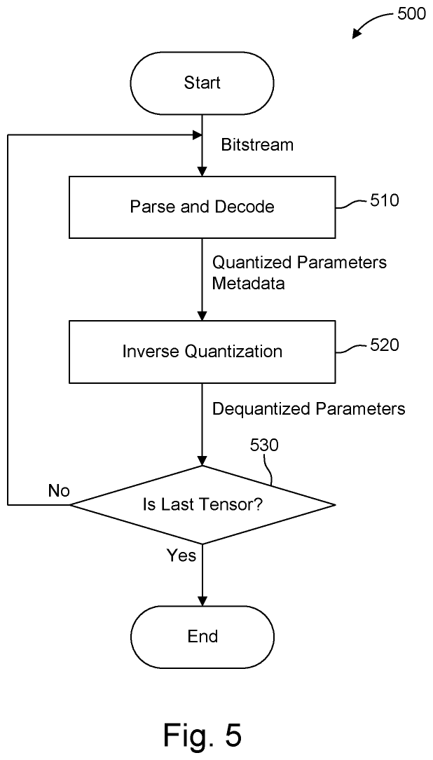

FIGS. 4 and 5 illustrate respectively at a high level a general process for encoding/decoding parameters of at least one tensor of at least one DNN, that can be used in at least some embodiments of the present disclosure.

In the exemplary embodiment of the compression method 400 of FIG. 4, the method 400 can comprise obtaining 410 (or in other words getting) parameters of the tensor to be compressed. The obtaining can for instance be performed by retrieving the parameters of at least one tensor from a storage unit, or by receiving the parameters from a data source via a communication interface.

As illustrated by FIG. 4, performing a compression of at least some parameters of a Neural Network can comprise:

Quantization 430 of the parameters (like Weights and Biases) of the Neural Network to represent them with a smaller number of bits;

Lossless entropy coding 440 of the quantized information.

Such a process can permit to represent the parameters with a smaller number of bits;

In some embodiments, the compression 400 can further comprise, prior to the quantization 430, a step of reducing 420 the number of parameters (or Weights or Biases) of the Neural Network by utilizing the inherent redundancies in the Neural Network. The reducing 420 thus provides at least one tensor of reduced dimensions, compared to the dimension of a tensor associated with a layer and input to the reducing step. For instance, the tensors of parameters of at least one layer of the DNN can be decomposed or made sparse in the reducing 420.

The resulting tensors, usually made of floating-point values, are quantized and entropy coded to compose the final bitstream, which is transmitted to the receivers.

This reducing 420 is optional and can thus be omitted in some embodiments.

Quantization of a tensor can involve approximating the values in the tensor (e.g. floating-point values) by values, like integer values, that requires a smaller number of bits than the input tensor.

Depending upon the DNN compression solutions, different kinds of quantization can be performed. Quantization can for instance be performed by using a uniform quantization or a non-uniform quantization like a Codebook-based quantization, as in some DNN compression solutions, notably in some compression standard like some upcoming standard ISO/MPEG7 relating to neural networks for multimedia content description and analysis, which is denoted hereinafter more simply MPEG NNR.

With Uniform quantization, a floating-point “step-size” can be defined and all floating-point values in a tensor can be represented as multiples of the step-size. The approximation of the tensor can be reconstructed at the decoder by simply multiplying the integer values by the “step-size”.

A Codebook is a set of values (like integer values or floating-point values) that the parameters of a layer can have, after quantization. Indices can be derived from the codebook values assigned to the parameters of the original tensor by the quantizing. To reconstruct an approximation of the original tensor, a decoding device uses the indexes to lookup the corresponding floating-point value from the codebook. Codebook-based quantization will be discussed in more detailed hereinafter.

As illustrated by FIG. 4, the parameters input to the quantization can be of floating-point type, while the output of the quantization can comprise one or more tensor of indices of integer type. Optionally, the quantization can also output the codebook to which the indices relate to. Indeed, in some embodiments, for instance in embodiments where the codebook is pre-fixed by the quantization, the codebook can be omitted in the output of the quantization.

According to FIG. 4, at least some of the outputs of the quantization 430 are used as input for performing a lossless entropy coding 440. The information input for the entropy coding (like, for quantized tensor, information regarding codebook and/or tensor of integer type) can be broken down in some embodiments to header information and payload comprising indexes.

Other elements (like a shape of the original tensor or symbol counts) can also be input to the entropy coding 440.

When several layers can be encoded by the encoding method 400, after encoding parameters associated to a layer, the method can be performed iteratively layer per layer for a DNN, until (450) the end of the encoding of parameters of the last layer to be encoded.

FIG. 5 depicts a decoding method 500 that can be used for decoding a bitstream obtained by the encoding method 400 already described. At the decoder, as illustrated by FIG. 5, the decoding method 500 can include some inverse operations (compared to the operations of the encoder side). For instance, the decoding method 500 can include parsing/entropy decoding 510 of the input bins to extract the quantized form of the parameters. Inverse quantization 520 can then be applied to derive the final values of the parameters. The matrix decomposition/sparsification of the tensors at the encoder usually does not require an inverse process at the decoder. For instance, the parameters that were set to zero at the reduction of parameters stage (reducing 420) can remain zero after inverse quantization at the decoder.

As illustrated by FIG. 5, the output of parsing and decoding 510 a bitstream corresponding to a layer of the DNN can comprise metadata and quantized parameters. For instance, when a codebook-based quantization has been performed at the encoder side, the output includes the codebook and the corresponding indices. For instance, both the codebook and the tensor of indices can be computed by the method of the K-means, which will derive a codebook of K values denoting the cluster centers and a tensor of indices that can have values belonging to the integer range [0 . . . K−1].

The decoding method can further comprise performing inverse quantization 520, using the decoded information (like the indices and the codebook).

When several layers can be decoded by the decoding method 500, the method 500 can be performed iteratively until (550) parameters of the last layer are encoded.

As illustrated by FIG. 4, at least some of the elements output by the quantization 430 are used as input for performing entropy coding 440, the way the quantization is implemented should be compliant with the way the entropy coding is performed, or vice-versa. This should be case for instance, whether the quantization is a uniform quantization or a codebook-based quantization (as quantization used in some compression solutions, like in the current upcoming standard MPEG-NNR)

However, this is not always the case. For instance, codebook-based quantization can present some disadvantages. For instance, the Codebook quantization can often be more efficient with larger tensors than with smaller tensors. One of the reasons is that the overhead of a codebook can become significant compared to the size of tensor if the tensor is small.

At least some embodiments of the present disclosure invention help to address this issue.

More precisely, according to a first aspect of the present disclosure, at least some embodiments propose to use Uniform quantization for smaller tensors and codebook quantization for larger tensors.

The present disclosure also proposed an exemplary format (also called hereinafter “unified format”), adapted to be used to several kind of quantizing, and notably cover both codebook and uniform quantization.

Entropy coding is a lossless data compression which works based on the fact that any data can be compressed if some data symbols are more likely to happen than others. Example of entropy coding methods include Huffman Coding and Arithmetic Coding.

The entropy of the quantized information directly affects the efficiency of arithmetic coding. If the quantized information has high entropy (e.g. high randomness), the arithmetic coding algorithm cannot compress the data efficiently. For example, if the symbols appear in the data with the same frequency (high randomness, high entropy) the compression would not be efficient. But if some symbols appear more frequently than others, the compression would be more efficient by using less bits for more frequent symbols.

According to a second aspect of the present disclosure, at least some embodiments propose a method that minimizes the entropy of quantized information so to help improving the efficiency of the arithmetic coding performed during entropy coding (e.g. conditional/and/or adaptive arithmetic coding)

The quantized information can be optimized (or at least improve) based on at least one first Mean Square Error(MSE) value (which controls distortion), e.g. by minimizing Mean Squared Error value while trying to minimize (or at least lowered) the entropy of quantized information (by using a pdf-bounded initialization of K-mean algorithm for instance).

The present disclosure relates to at several aspects. Some aspects, like the first and second aspects, introduced above, can be implemented in a same embodiment and or separately (some embodiment implementing both aspects, while some embodiments implementing only one of the aspects). For instance, in some embodiments, a binary search for symbol count can be performed while not optimizing the pdf factor according to MSE. Embodiments combining both binary search for symbol count and optimizing the pdf factor according to MSE can however often help obtaining better rate/distortion results, than when the quantization only tries to minimize the error (MSE) between the quantized and original tensors Furthermore, in some embodiments of the present disclosure, quantization, as described herein, for instance codebook quantization (like in link with the second aspect) and conditional and/or adaptive arithmetic coding can be combined.

It is to be pointed out that the embodiments of the methods of the present disclosure detailed herein can be implemented in many compression solutions and are not limited to a specific standard, even at least some of the embodiments can for instance apply in the context of some compression standards, like some draft standard developed by ISO/MPEG7.

### Binary Search for “Best” Symbol Count

Term Symbol count, which designates in general the number of all symbols that are possible to appear at the input of entropy coding, is in case of codebook quantization the codebook size.

In some compression framework, parameters input to the quantization step can sometimes comprise a “qBit” value indicating a number of bits for representation of each symbol of a codebook, the codebook size being thus equal to 2^{qBits}.

However, in embodiments where arithmetic coding (or conditional and/or adaptive arithmetic coding) is used after quantization, the codebook size does not need to be a power of 2. According to at least some embodiments of the present disclosure, a codebook size (being not necessarily a power of 2) can be obtained (or determined) for a first (specified) accuracy.

More precisely, according to some embodiments of the present disclosure, instead of specifying a “qBit” value, a first distortion value between the original and quantized tensors can be specified at the encoder, for instance a desired maximum distortion value, like a desired maximum Mean Square Error (MSE) value (denoted hereinafter MaxMSE). The codebook size can thus be obtained, according to this first MSE value, by using a binary search for instance.

In some embodiments of the present disclosure, the binary search can be done over the range of codebook sizes, for instance a range of 4 to 4096 for the codebook size (equivalent of “qBits” 2 to 12).

Obviously, upon embodiments, the lowest and largest values of the range, like the lowest and largest values of “qBit” can vary upon embodiments, and numeral values (e.g. 4 or 4096 for codebook size) are only exemplary values. For instance, values of qBits from 2 to 20 (and corresponding codebook sizes) can be used in some embodiments)

Depending upon embodiments, binary search can be applied to values monotonically increasing or decreasing. Indeed, increasing the symbol count (or codebook size) decreases MSE monotonically. Thus, the best (smallest) symbol count can be obtained, for a given MSE value (maxMSE), using a binary search.

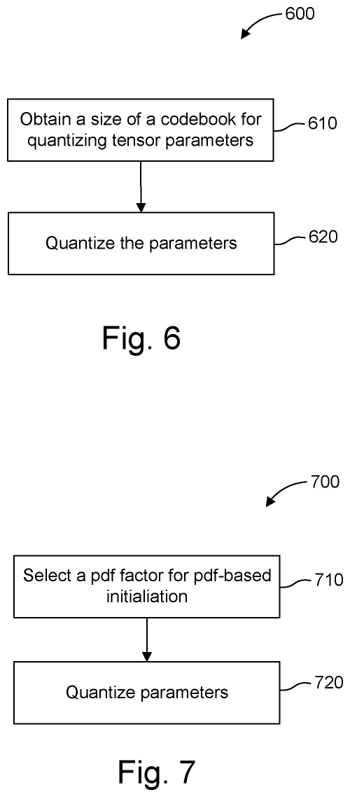

FIG. 6 illustrates an example of a method 600 for quantizing parameters of a tensor of a layer of DNN according to an embodiment. At 601, a size of a codebook for quantizing parameters of at least one tensor of a DNN is obtained. The size of the codebook is obtained according to a distortion value determined between the at least one tensor and a quantized version of said at least one tensor, as described above. In a variant, the size of the codebook is obtained using a binary search over a range of codebook sizes. At 602, the parameters of the tensor are quantized using a codebook having the size obtained at 601. Embodiments described in relation with FIG. 6 can be implemented in the method for encoding a DNN described in relation with FIG. 4.

### Lowering Entropy Quantization Using Pdf-Based Initialization

Some quantizing solutions can be based on a pdf-based initialization, like pdf-based initialization of K-Means clusters. For instance, use of bounds for the pdf function can help to control how uniformly the initial K-means clusters (more precisely the values of the centers of the K-mean clusters used for K-means initialization) are spaced from each other. If the initialization is completely based on pdf, more initial clusters are assigned to symbols with higher frequency. While this can help improving the accuracy of quantization (i.e. reducing distortion), it can also make the cluster populations (i.e. the number of symbols in each cluster) closer to each other which would eventually hurt the entropy and thus increase the size of bitstream (i.e. increasing rate, when considering, in the context of rate-distortion, MSE and network inference error rate as distortion and the size of compressed model as rate. The size would thus be proportional to the bitrate if we would want to send the model in a fixed amount of time.)

According to at least some embodiments of the present disclosure, a “pdf Factor” is defined that indicates how PDF based initialization, is applied to the quantization (e.g. the K-Means quantization). Depending upon embodiments of the present disclosure, the format of the pdf factor can vary.

For instance, in some embodiments, the “pdf Factor” can be a number between 0.0 and 1.0. In such embodiments, the “pdf Factor” is thus representative of how much we want to apply the PDF-based initialization. If the pdf Factor” has the value “0”, it means we do not want to use PDF based initialization at all. In this case the K-Means algorithm is initialized uniformly. A value of 1.0 for pdf Factor”, means we want to use PDF feature with its maximum effect. (for instance, with the formula below, the lower bound becomes zero and upper bound becomes twice the average value).

In some embodiments, an exemplary bounded PDF function used for the initialization of K-Means can be defined as follows:

BoundedPDF=Clip(PDF, LowerBound, UpperBound)

### Where:

LowerBound=(1.0−pdfFactor)*Avg(PDF)

UpperBound=(1.0+pdfFactor)*Avg(PDF)

where PDF is the probability density function, which can give a likelihood of a random variable taking a specific value.

As explained above, according to at least some embodiments of the present disclosure, one of the inputs to the quantization algorithm can be a first distortion value (like a desired maximum MSE value MaxMSE). The quantization algorithm can for instance use a binary search algorithm at the encoder side to find the minimum number of symbols (i.e. codebook size) needed to quantize the tensor while keeping the distortion (or error) under the specified maximum value. (MSE<=maxMSE)

In at least some embodiments of the present disclosure, the pdf Factor can be varied to improve the entropy of the quantized information while quantizing with a specific symbol-count (or codebook size). For instance, when the values of the pdf factor can be defined in a range comprised between a first pdf factor value and a second pdf factor value, the value of the pdf Factor can be varied from the first value to the second value, with a constant and/or variable step, and the entropy of quantized information can be computed for each value of the pdf factor, so as to choose the pdf factor that corresponds with the lowest entropy.

According to a first example, we can change the value of the pdf Factor increasingly in a range from the lowest pdf Factor value to the highest pdf Factor value (e.g. from 0 to 1) using steps (e.g. steps of 0.1) and calculate the entropy of quantized information for each value of the pdf factor. According to a second example, we can change the pdf Factor decreasingly in a range from the highest pdf Factor value to the lowest pdf Factor value (e.g. from 1 to 0) using steps of 0.1 and calculate the entropy of quantized information for each pdf factor. We then choose the pdf factor that corresponds with the lowest entropy with the first and/or second example.

In at least some of the embodiments of the present disclosure, two nested loops can be performed: a first loop helping optimizing for MSE (like the binary search that finds best symbol-count given a maxMSE value) and a second loop helping optimizing for entropy (The search for pdf Factor that results in the lowest entropy).

At least some of the embodiments of the present disclosure can implement the first loop helping to optimize for MSE but not the second loop helping to optimize for entropy or vice versa.

For instance, optimizing codebook size for MSE can be performed in embodiments when codebook quantization initialization methods other than bounded pdf quantization is used, and bounded pdf quantization using a pdf Factor lowering entropy can be performed with a codebook size determined from an input q-bit as explained above.

FIG. 7 illustrates an example of a method 700 for quantizing parameters of a tensor of a layer of DNN according to the embodiment described above. At 701, a pdf factor is selected among several candidate bounding pdf factors, based on an entropy obtained for the quantized parameters from each one of the several candidate bounding pdf factors, as described above. At 702, the parameters of the tensor are quantized using a pdf-based initialization bounded according to the selected pdf factor. Embodiments described in relation with FIG. 7 can be implemented in the method for encoding a DNN described in relation with FIG. 4.

In an embodiment, as indicated above, the methods illustrated respectively with FIGS. 6 and 7 can be combined.

### Unified Codebook Information

At least some of the embodiments of the present disclosure also proposes an exemplary codebook format (Unified Codebook Information”) adapted to be used for several kind of quantization, and that can notably cover both codebook and uniform quantization.

In at least some embodiments of the present disclosure Unified Codebook Information can correspond to an array of integers (noted Codebook Info hereinafter).

The Unified Codebook Information can comprise a first information representative of a type of the codebook. For instance, in an exemplary format where the Unified Codebook Information is an array of integers, the first integer in the array can specify the type of codebook. Examples of type of codebook are listed below.

Some entries in the Unified Codebook Information can depend on the codebook type. For instance, with the above exemplary format, the entries following the first integer in the Unified Codebook Information can depend on the codebook type.

For some types of codebook (like for below types “1” and “2”), the actual quantized tensor can be omitted in the bitstream (i.e. no indexes are encoded in the bit stream), as the codebook information contains all the information needed to reconstruct the tensor.

Examples of types of codebook and associated unified codebook information are given below. Of course, notation and/or numbering of the types are only exemplary and cannot be considered as limitative of the present disclosure.

Codebook Type 1: All tensor entries have the same integer value.
This is a rare case that happens sometimes in the bias tensors (as for example in for some convolutional layers of the image classification neural network “ResNet50” studied in the MPEG-NNR)
Codebook Info: [1, intVal]
Where intVal is the integer value for all entries of the tensor.

Codebook Type 2: All tensor entries have almost the same floating-point value.
This means that if a uniform quantization of the tensor has been performed, all resulting integer values would be the same.
This is a rare case that happens sometimes in the bias tensors (For example in “ResNet50”)
Codebook Info: [2, rangeInt, symCount, offset]
The floating-point values floatVal used for entries of the tensor can be calculated as follows:
   step=float(rangeInt)/(symCount−1)
   floatVal=offset*step
The “symCount” is the symbol count for the quantization which is obtained by the quantization algorithm (Binary search based on the maxMSE). The values for “rangeInt” and “offset” are calculated, using mathematical functions ceil and floor for instance, from the original tensor as follows:
rangeInt=ceil(max(tensor))−floor(min(tensor))
step=float(rangeInt)/(symCount−1)
offset=round(min(tensor)/step

Codebook Type 3: Uniform quantization of the tensor.
Codebook Info: [3, rangeInt, symCount, offset]
For each integer entry “q” in the quantized tensor, the corresponding floating-point entry “r” in the reconstructed tensor can be calculated as follows:
   step=float(rangeInt)/(symCount−1)
   r=(q+offset)*step
Where rangeInt, symCount, offset have similar meaning than above

Codebook Type 0: Codebook quantization.
Codebook Info: [0, cbRangeInt, cbSymCount, cbOffset, cbInt₀, cbInt₁, cbInt_{N-1}]

In this case the cbInt₀ to cbInt_{N-1} entries of the array “Codebook info” are the N entries of codebook quantized to integer values. We first reconstruct, at the decoder side for instance, the floating-point codebook and then use it to reconstruct (i.e. lookup) the tensor entries. Assuming rcbFloatᵢ is the floating-point reconstructed codebook entry corresponding to the integer cbIntᵢ in the codebook info, we can reconstruct the codebook as follows:
cbStep=float(cbRangeInt)/(cbSymCount−1)
rcbFloatᵢ=(cbIntᵢ+cbOffset)*cbStep
recCodebook=[rcbFloat₀, rcbFloat₁, . . . , rcbFloat_{N-1}]
   where recCodebook represents the codebook reconstructed from Codebook info

For each integer entry “q” in the quantized tensor (i.e. in the “indexes”), the corresponding floating-point entry “r” in the reconstructed tensor is:
r=recCodebook[q]

On the encoding side, the original codebook after K-mean quantization is:
floatCodebook=[cbFloat₀, cbFloat₁, . . . , cbFloat_{N-1}]

The values for “cbRangeInt”, “cbSymCount”, and “cbOffset” can be set after codebook quantization of the tensor as follows:
cbRangeInt=ceil(max(floatCodebook))−floor(min(floatCodebook))
cbSymCount=max(MinCbSymCount, symCount²)
cbStep=float(cbRangeInt)/(cbSymCount−1)
cbOffset=round(min(floatCodebook)/step)
cbInt₁=round(cbFloatᵢ/cbStep)−cbOffset
where cbIntᵢ is the quantized integer value corresponding to the i^{th} entry in the original floating-point codebook cbFloatᵢ.
where MinCbSymCount represents a maximum value of codebook sizes that can vary upon embodiments and be equal to 2²⁰ or 2¹² (=4096).

As a non-limitative example, while some embodiments can be applied in non-standardized technologies, some embodiments can be used in contexts of standards for DNN compression/decompression, like the upcoming standard ISO/MPEG7 relating to compressed representations of neural networks for multimedia content description and analysis, which is denoted hereinafter more simply MPEG NNR.

Some embodiments of the present disclosure can comprise transmitting/receiving signaling information between an encoder and a decoder. This signaling information is presented in the present disclosure in link with an exemplary, non-limitative, syntax. This exemplary syntax is based, for the ease of explanation, on a syntax used in an exemplary MPEG NNR draft standard (N19225-Working Draft 4 of Compression of neural networks for multimedia content description and analysis». International Organization for Standardization ISO/IEC JTC1/SC29/WG11, April. 2020, the differences with this exemplary MPEG NRR syntax being underlined in the syntax tables.

The following syntax is just an exemplary syntax that does not limit the present disclosure. For instance, numbers of bits used for syntax elements are exemplary embodiments. For ease of understanding, in the exemplary syntax, the following identifiers and clauses according to embodiments of the present disclosure have been added with a numbering of sections and tables being kept aligned with the current exemplary working draft of the MPEG-NNR.

According to the exemplary syntax detailed herein, a bitstream can be split into units that represent one tensor. The parameters included in the header of each unit, namely the nnr_compressed_data_unit_header.

The exemplary syntax is detailed in link with a current version of the MPEG NRR draft standard which specify a parsing of the codebook_size codebook entries, store as float32 values, as shown below.

| | |
|---|---|
| nnr_compressed_data_unit_header( ) { | Descriptor |
| nnr_compressed_data_unit_payload_type | u(5) |
| nnr_multiple_topology_elements_present_flag | u(1) |
| nnr_decompressed_data_format_present_flag | u(1) |
| input_parameters_present_flag | u(1) |
| if (nnr_multiple_topology_elements_present_flag == 1) | |
| topology_elements_ids_list( ) | |
| Else | |
| ref_id | st(v) |
| if (nnr_compressed_data_unit_payload_type == NNR_PT_CB_FLOAT32) { | |
| codebook_zero_offset | u(8) |
| codebook_size | u(16) |
| For ( j = 0 ; j < codebook_size; j++ ) { | |
| codebook[j] | flt(32) |
| } | |
| } | |
| if (nnr_decompressed_data_format_present_flag == 1) | |
| nnr_decompressed_data_format | u(7) |
| if (input_parameters_present_flag == 1) { | |
| tensor_dimensions_flag | u(1) |
| cabac_unary_length_flag | u(1) |
| if (tensor_dimensions_flag == 1) | |
| tensor_dimensions( ) | |
| If (cabac_unary_length_flag == 1) | |
| cabac_unary_length | u(8) |
| } | |
| byte_alignment( ) | |
| } | |

According to at least some embodiments of the present disclosure, using the exemplary syntax introduced above, it is proposed to modify the definition of nnr_compressed_data_unit_header( ), to be adapted to support the proposed codebook mechanism (or format) according to the present principles. The new parts are underlined.

| | |
|---|---|
| nnr_compressed_data_unit_header( ) { | Descriptor |
| nnr_compressed_data_unit_payload_type | u(5) |
| nnr_multiple_topology_elements_present_flag | u(1) |
| nnr_decompressed_data_format_present_flag | u(1) |
| input_parameters_present_flag | u(1) |
| if (nnr_multiple_topology_elements_present_flag == 1) | |
| topology_elements_ids_list( ) | |
| else | |
| ref_id | st(v) |
| if (nnr_compressed_data_unit_payload_type == NNR_PT_CB) | |
| codebook_info( ) | |
| if (nnr_decompressed_data_format_present_flag == 1) | |
| nnr_decompressed_data_format | u(7) |
| if (input_parameters_present_flag == 1) { | |
| tensor_dimensions_flag | u(1) |
| cabac_unary_length_flag | u(1) |
| if (tensor_dimensions_flag == 1) | |
| tensor_dimensions( ) | |
| If (cabac_unary_length_flag == 1) | |
| cabac_unary_length | u(8) |
| } | |
| byte_alignment( ) | |
| } | |
| codebook_info( ) { | |
| codebook_type | u(v) |
| if ( codebook_type == 0) { | |
| cbRangeInt | u(v) |
| cbSymCount | u(v) |
| cbOffset | i(v) |
| codebook_size | u(v) |
| for ( j= 0 ; j < codebook_size; j++ ) { | |
| codebook_int[j] | u(v) |
| } | |
| } | |
| else if ( codebook_type == 1) { | |
| tensor_int_value | u(v) |
| else if ( codebook_type == 2 \| \| codebook_type == 3) { | |
| rangeInt | u(v) |
| symCount | u(v) |
| offset | i(v) |
| } | |

With the above exemplary syntax, all signed and unsigned integer values in this table use variable number of bytes. In some exemplary implementation, we used the functions defined below to serialize/deserialize these integer values to/from a byte-stream. Other variable-length methods for serializing/de-serializing can be used in other embodiments.

### Exemplary Functions to Serialize/Deserialize These Integer Values to/from a Byte-Stream

The following functions can be used to serialize a signed/unsigned integer to byte-streams. The number of bytes used for in the byte-stream can depend on the integer value.

```
def uint2ByteList(val):
  # range: 0 .. 536870911 (=2\hat{ }29 − 1)
  assert val<536870912, ″uint2ByteList function can only handle
values between 0 and 536,870,911″
  byteList = [ val&0x7F ]
```

| | |
|---|---|
| if val>=128: | # 2\hat{ }7 |

```
    byteList[0] += 128
    byteList += [ (val>>7)&0x7F ]
```

| | |
|---|---|
| if val>=16384: | # 2\hat{ }14 |

```
    byteList[1] += 128
    byteList += [ (val>>14)&0x7F ]
```

| | |
|---|---|
| if val>=2097152: | # 2\hat{ }21 |

```
    byteList[2] += 128
    byteList += [ (val>>21 )&0xFF ]
  return bytearray(byteList)
def int2ByteList(val):
  # range: −268435455 .. 268435455 (= +/− 2\hat{ }28 − 1)
  isNeg = val<0
  if isNeg: val = −val
  assert val<268435456, “int2ByteList function can only handle
values between −268,435,455 and 268,435,456”
  byteList = [ val&0x3F ]
  if isNeg: byteList[0] += 128
```

| | |
|---|---|
| if val>=64: | # 2\hat{ }6 |

```
    byteList[0] += 64
    byteList += [ (val>>6)&0x7F ]
```

| | |
|---|---|
| if val>=8192: | # 2\hat{ }13 |

```
    byteList[1] += 128
    byteList += [ (val>>13)&0x7F ]
```

| | |
|---|---|
| if val>=1048576: | # 2\hat{ }20 |

```
    byteList[2] += 128
    byteList += [ (val>>20)&0xFF ]
  return bytearray(byteList)
```

The following functions deserialize the signed/unsigned integer from a byte-stream when decoding the bitstream.

| def byteList2Uint(byteList, offset=None): | |
|---|---|
| dataBytes = byteList if offset is None else byteList[offset:] | |
| uintLen = 4 | |
| uintValue = dataBytes[0]&0x7F | |
| if dataBytes[0]<128: | uintLen = 1 |
| else: | |
| uintValue += (np.uint32(dataBytes[1]&0x7F)<<7) | |
| if dataBytes[1]<128: | uintLen = 2 |
| else: | |
| uintValue += (np.uint32(dataBytes[2]&0x7F)<<14) | |
| if dataBytes[2]<128: | uintLen = 3 |
| else: | |
| uintValue += (np.uint32(dataBytes[3])<<21) | |
| if offset is None: return np.uint32(uintValue) | |
| return np.uint32(uintValue), (offset+uintLen) | |
| def byteList2Int(byteList, offset=None): | |
| dataBytes = byteList if offset is None else byteList[offset:] | |
| intLen = 4 | |
| intValue = dataBytes[0]&0x3F | |
| if (dataBytes[0]&0x7F)<64 | intLen = 1 |
| else: | |
| intValue += (np.uint32(dataBytes[1]&0x7F)<<6) | |
| if dataBytes[1]<128: | intLen = 2 |
| else: | |
| intValue += (np.uint32(dataBytes[2]&0x7F)<<13) | |
| if dataBytes[2]<128: | intLen = 3 |

```
      else:
        intValue += (np.uint32(dataBytes[3])<<20)
  if dataBytes[0]>=128: intValue = −intValue # Apply Signbit
  if offset is None: return np.int32(intValue)
  return np.int32(intValue), (offset+intLen)
```

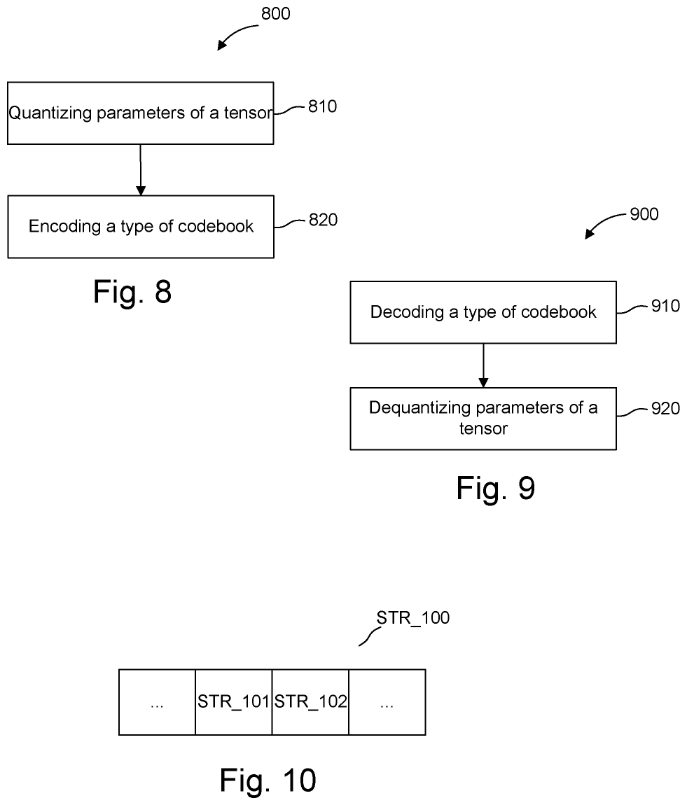

FIG. 8 illustrates an example of a method 800 for encoding a DNN according to an embodiment. At 810, parameters of a tensor of a layer of DNN are quantized using a codebook and encoded in a bitstream.

For quantizing the parameters, a codebook having a type as defined above is used. As described above, in order to signal to the decoder, the type of codebook used, at 820, an information representative of the type of the codebook used to quantize the tensor parameters is encoded in the bitstream.

FIG. 9 illustrates an example of a method 900 for decoding a DNN according to an embodiment. At 910, an information representative of a type of a codebook is decoded from an input bitstream comprising data representative of at least one tensor of a layer of a DNN. At 920, as described above, parameters of the tensor are decoded from the bitstream and dequantized using a codebook having a type indicated by the decoded information.

Embodiments of the encoding method 800 and decoding method 900 described in relation with FIGS. 8 and 9 respectively can be implemented in the respective method for encoding a DNN described in relation with FIG. 4 and the method for decoding a DNN described in relation with FIG. 5. In some embodiments, the aspects described above and in relation with FIGS. 6, 7 and 8 can be combined.

FIG. 10 illustrates an example of a part of a bitstream STR_100 comprising data representative of a tensor of at least one layer of a Deep Neural Network generated according to an embodiment. The bitstream is for instance generated according to any one of the embodiments described above. The part illustrated on FIG. 10 comprises data representative of the tensor (STR_101) and an information (STR_102) representative of a type of a codebook used for quantizing the parameters of the tensor.

### Additional Embodiments and Information

This application describes a variety of aspects, including tools, features, embodiments, models, approaches, etc. Many of these aspects are described with specificity and, at least to show the individual characteristics, are often described in a manner that may sound limiting. However, this is for purposes of clarity in description, and does not limit the application or scope of those aspects. Indeed, all of the different aspects can be combined and interchanged to provide further aspects. Moreover, the aspects can be combined and interchanged with aspects described in earlier filings as well.

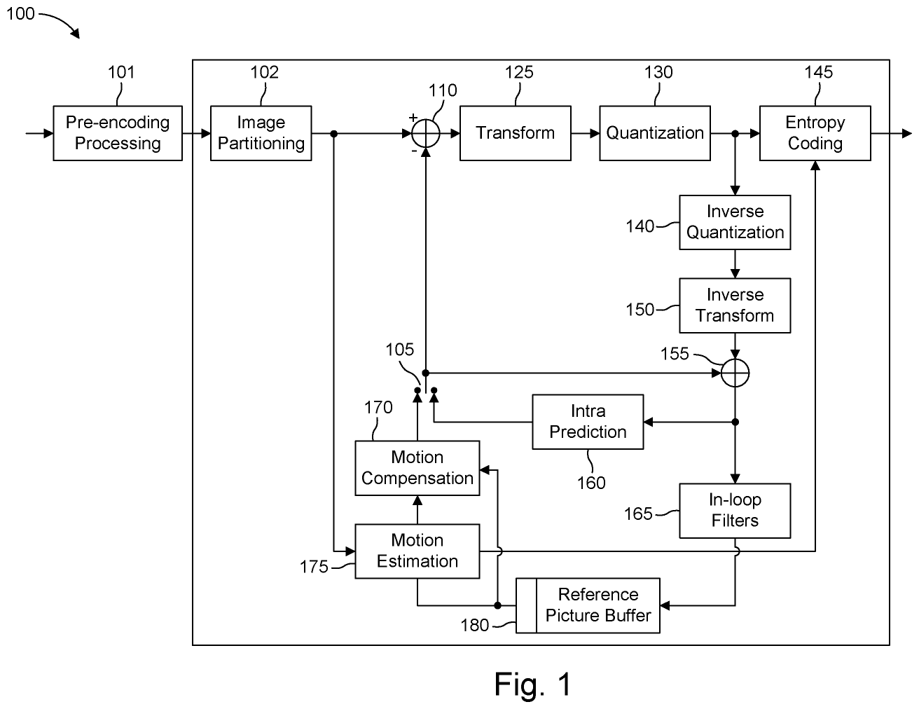

The aspects described and contemplated in this application can be implemented in many different forms. FIGS. 1, 2 and 3 below provide some embodiments, but other embodiments are contemplated and the discussion of FIGS. 1, 2 and 3 does not limit the breadth of the implementations. At least one of the aspects generally relates to encoding and decoding (for instance, video encoding and decoding, and/or encoding and decoding of at least some parameters of at least some layer of a DNN), and at least one other aspect generally relates to transmitting a bitstream generated or encoded. These and other aspects can be implemented as a method, an apparatus, a computer readable storage medium having stored thereon instructions for encoding or decoding data according to any of the methods described, and/or a computer readable storage medium having stored thereon a bitstream generated according to any of the methods described.

In the present application, the terms “reconstructed” and “decoded” may be used interchangeably, the terms “pixel” and “sample” may be used interchangeably, the terms “image,” “picture” and “frame” may be used interchangeably. Usually, but not necessarily, the term “reconstructed” is used at the encoder side while “decoded” is used at the decoder side.

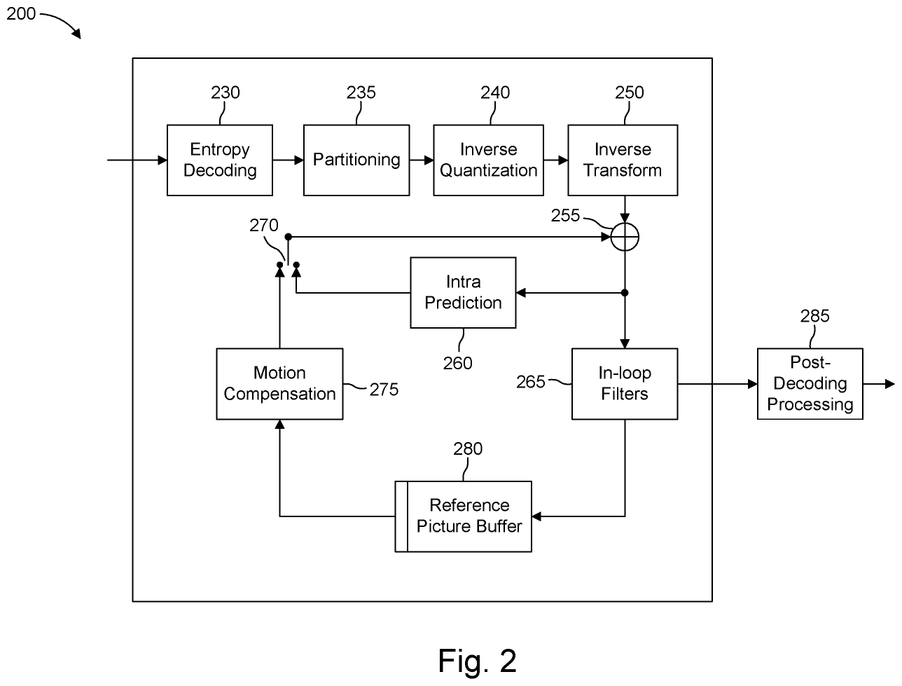

Various methods and other aspects described in this application can be used to modify modules, for example, the intra prediction, entropy coding, and/or decoding modules (160, 260, 145, 230), of an encoder 100 and decoder 200 as shown in FIG. 1 and FIG. 2. Moreover, the present aspects are not limited to VVC or HEVC, and can be applied, for example, to other standards and recommendations, whether pre-existing or future-developed, and extensions of any such standards and recommendations (including VVC and HEVC).

Moreover, the present aspects are not limited to VVC or HEVC, or even to video data, and can be applied to an encoder or decoder adapted to encode, respectively decode, at least one tensor of at least one layer of a neural network that can be used in many technical fields other than video (of course, in such embodiments, some modules like intra prediction module 160 can be optional)

Unless indicated otherwise, or technically precluded, the aspects described in this application can be used individually or in combination.

Various numeric values are used in the present application (for example range of a pdf factor, or step for varying pdf factor or maximum codebook size used for some computing). The specific values are for example purposes and the aspects described are not limited to these specific values.

FIG. 1 illustrates an encoder 100. Variations of this encoder 100 are contemplated, but the encoder 100 is described below for purposes of clarity without describing all expected variations.

Before being encoded, the sequence may go through pre-encoding processing (101), for example, applying a color transform to the input color picture (e.g., conversion from RGB 4:4:4 to YCbCr 4:2:0) in case of a video sequence, or performing a remapping of the input picture components in order to get a signal distribution more resilient to compression (for instance using a histogram equalization of one of the color components). Also, pre-encoding processing can include binarization as the exemplary binarization detailed above in link with CABAC.

Metadata can be associated with the pre-processing and attached to the bitstream.

In the encoder 100, in case of a video sequence, a picture is encoded by the encoder elements as described below. The picture to be encoded is partitioned (102) and processed in units of, for example, CUs. Each unit is encoded using, for example, either an intra or inter mode. When a unit is encoded in an intra mode, it performs intra prediction (160). In an inter mode, motion estimation (175) and compensation (170) are performed. The encoder decides (105) which one of the intra mode or inter mode to use for encoding the unit, and indicates the intra/inter decision by, for example, a prediction mode flag. Prediction residuals are calculated, for example, by subtracting (110) the predicted block from the original image block.

The prediction residuals are then transformed (125) and quantized (130).

The quantized transform coefficients, as well as motion vectors and other syntax elements, are entropy coded (145) to output a bitstream.

The encoder can skip the transform and apply quantization directly to the non-transformed residual signal. The encoder can bypass both transform and quantization, i.e., the residual is coded directly without the application of the transform or quantization processes.

The encoder decodes an encoded block to provide a reference for further predictions. The quantized transform coefficients are de-quantized (140) and inverse transformed (150) to decode prediction residuals. For instance, in case of a video sequence, combining (155) the decoded prediction residuals and the predicted block, an image block is reconstructed. In-loop filters (165) are applied to the reconstructed picture to perform, for example, deblocking/SAO (Sample Adaptive Offset) filtering to reduce encoding artifacts. The filtered image is stored at a reference picture buffer (180).

FIG. 2 illustrates a block diagram of a decoder 200. In the decoder 200, a bitstream is decoded by the decoder elements as described below. Decoder 200 generally performs a decoding pass almost reciprocal, to the encoding pass as described in FIG. 1. The encoder 100 also generally performs decoding as part of encoding data.

In particular, the input of the decoder 200 includes a bitstream, which can be generated by encoder 100. The bitstream is first entropy decoded (230) to obtain transform coefficients, motion vectors, and other coded information.

In case of a video bitstream, the picture partition information indicates how the picture is partitioned. The decoder may therefore divide (235) the picture according to the decoded picture partitioning information. The transform coefficients are de-quantized (240) and inverse transformed (250) to decode the prediction residuals. Combining (255) the decoded prediction residuals and the predicted block, an image block is reconstructed. The predicted block can be obtained (270) from intra prediction (260) or motion-compensated prediction (i.e., inter prediction) (275). In-loop filters (265) are applied to the reconstructed image. The filtered image is stored at a reference picture buffer (280).

The decoded element (like the picture or the layer parameters) can further go through post-decoding processing (285), for example, in case of a decoded image, an inverse color transform (e.g. conversion from YCbCr 4:2:0 to RGB 4:4:4) or an inverse remapping performing the inverse of the remapping process performed in the pre-encoding processing (101). The post-decoding processing can use metadata derived in the pre-encoding processing and signaled in the bitstream.

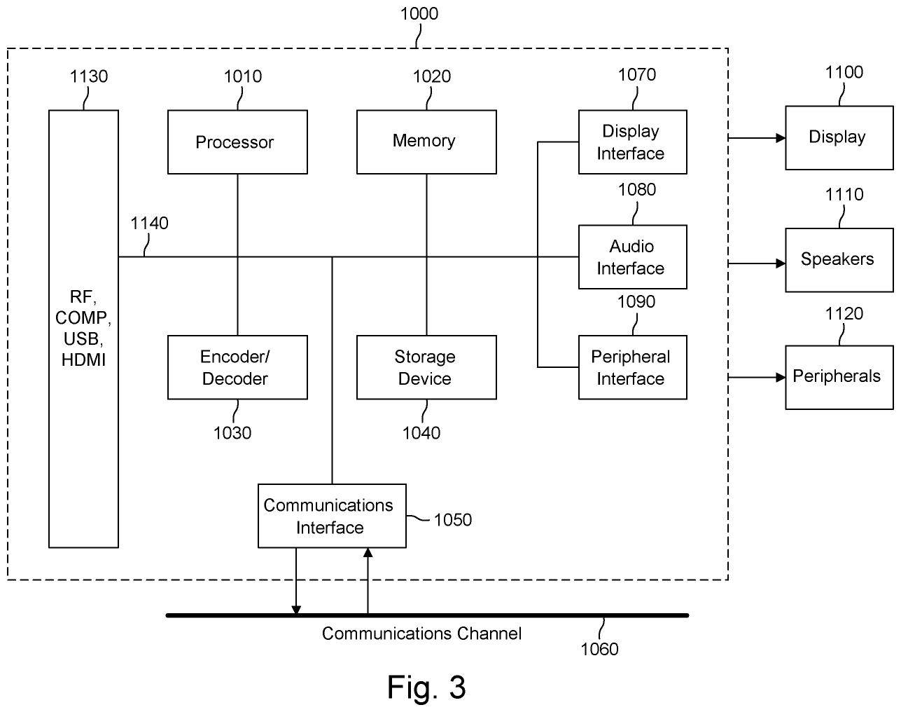

FIG. 3 illustrates a block diagram of an example of a system in which various aspects and embodiments are implemented. System 1000 can be embodied as a device including the various components described below and is configured to perform one or more of the aspects described in this document. Examples of such devices include, but are not limited to, various electronic devices such as personal computers, laptop computers, smartphones, tablet computers, digital multimedia set top boxes, digital television receivers, personal video recording systems, connected home appliances, and servers. Elements of system 1000, singly or in combination, can be embodied in a single integrated circuit (IC), multiple ICs, and/or discrete components. For example, in at least one embodiment, the processing and encoder/decoder elements of system 1000 are distributed across multiple ICs and/or discrete components. In various embodiments, the system 1000 is communicatively coupled to one or more other systems, or other electronic devices, via, for example, a communications bus or through dedicated input and/or output ports. In various embodiments, the system 1000 is configured to implement one or more of the aspects described in this document.

The system 1000 includes at least one processor 1010 configured to execute instructions loaded therein for implementing, for example, the various aspects described in this document. Processor 1010 can include embedded memory, input output interface, and various other circuitries as known in the art. The system 1000 includes at least one memory 1020 (e.g., a volatile memory device, and/or a non-volatile memory device). System 1000 includes a storage device 1040, which can include non-volatile memory and/or volatile memory, including, but not limited to, Electrically Erasable Programmable Read-Only Memory (EEPROM), Read-Only Memory (ROM), Programmable Read-Only Memory (PROM), Random Access Memory (RAM), Dynamic Random-Access Memory (DRAM), Static Random-Access Memory (SRAM), flash, magnetic disk drive, and/or optical disk drive. The storage device 1040 can include an internal storage device, an attached storage device (including detachable and non-detachable storage devices), and/or a network accessible storage device, as non-limiting examples.

System 1000 includes an encoder/decoder module 1030 configured, for example, to process data to provide an encoded or decoded data stream (such a video stream and/or a stream representative of at least one parameter at least one tensor of at least one layer of at least one DNN), and the encoder/decoder module 1030 can include its own processor and memory. The encoder/decoder module 1030 represents module(s) that can be included in a device to perform the encoding and/or decoding functions. As is known, a device can include one or both of the encoding and decoding modules. Additionally, encoder/decoder module 1030 can be implemented as a separate element of system 1000 or can be incorporated within processor 1010 as a combination of hardware and software as known to those skilled in the art.

Program code to be loaded onto processor 1010 or encoder/decoder 1030 to perform the various aspects described in this document can be stored in storage device 1040 and subsequently loaded onto memory 1020 for execution by processor 1010. In accordance with various embodiments, one or more of processor 1010, memory 1020, storage device 1040, and encoder/decoder module 1030 can store one or more of various items during the performance of the processes described in this document. Such stored items can include, but are not limited to, the input video, the decoded video or portions of the decoded video, data representative of at least one parameter of at least one tensor of at least one layer of the at least one DNN, the bitstream, matrices, variables, and intermediate or final results from the processing of equations, formulas, operations, and operational logic.

In some embodiments, memory inside of the processor 1010 and/or the encoder/decoder module 1030 is used to store instructions and to provide working memory for processing that is needed during encoding or decoding. In other embodiments, however, a memory external to the processing device (for example, the processing device can be either the processor 1010 or the encoder/decoder module 1030) is used for one or more of these functions. The external memory can be the memory 1020 and/or the storage device 1040, for example, a dynamic volatile memory and/or a non-volatile flash memory. In several embodiments, an external non-volatile flash memory is used to store the operating system of, for example, a television. In at least one embodiment, a fast external dynamic volatile memory such as a RAM is used as working memory for coding and decoding operations, such as for MPEG-2 (MPEG refers to the Moving Picture Experts Group, MPEG-2 is also referred to as ISO/IEC 13818, and 13818-1 is also known as H.222, and 13818-2 is also known as H.262), HEVC (HEVC refers to High Efficiency Video Coding, also known as H.265 and MPEG-H Part 2), or VVC (Versatile Video Coding, a new standard being developed by JVET, the Joint Video Experts Team).

The input to the elements of system 1000 can be provided through various input devices as indicated in block 1130. Such input devices include, but are not limited to, (i) a radio frequency (RF) portion that receives an RF signal transmitted, for example, over the air by a broadcaster, (ii) a Component (COMP) input terminal (or a set of COMP input terminals), (iii) a Universal Serial Bus (USB) input terminal, and/or (iv) a High Definition Multimedia Interface (HDMI) input terminal. Other examples, not shown in FIG. 3, include composite video.

In various embodiments, the input devices of block 1130 have associated respective input processing elements as known in the art. For example, the RF portion can be associated with elements suitable for (i) selecting a desired frequency (also referred to as selecting a signal, or band-limiting a signal to a band of frequencies), (ii) down converting the selected signal, (iii) band-limiting again to a narrower band of frequencies to select (for example) a signal frequency band which can be referred to as a channel in certain embodiments, (iv) demodulating the down converted and band-limited signal, (v) performing error correction, and (vi) demultiplexing to select the desired stream of data packets. The RF portion of various embodiments includes one or more elements to perform these functions, for example, frequency selectors, signal selectors, band-limiters, channel selectors, filters, downconverters, demodulators, error correctors, and demultiplexers. The RF portion can include a tuner that performs various of these functions, including, for example, down converting the received signal to a lower frequency (for example, an intermediate frequency or a near-baseband frequency) or to baseband. In one set-top box embodiment, the RF portion and its associated input processing element receives an RF signal transmitted over a wired (for example, cable) medium, and performs frequency selection by filtering, down converting, and filtering again to a desired frequency band. Various embodiments rearrange the order of the above-described (and other) elements, remove some of these elements, and/or add other elements performing similar or different functions. Adding elements can include inserting elements in between existing elements, such as, for example, inserting amplifiers and an analog-to-digital converter. In various embodiments, the RF portion includes an antenna.

Additionally, the USB and/or HDMI terminals can include respective interface processors for connecting system 1000 to other electronic devices across USB and/or HDMI connections. It is to be understood that various aspects of input processing, for example, Reed-Solomon error correction, can be implemented, for example, within a separate input processing IC or within processor 1010, as necessary. Similarly, aspects of USB or HDMI interface processing can be implemented within separate interface ICs or within processor 1010, as necessary. The demodulated, error corrected, and demultiplexed stream is provided to various processing elements, including, for example, processor 1010, and encoder/decoder 1030 operating in combination with the memory and storage elements to process the data stream as necessary for presentation on an output device.

Various elements of system 1000 can be provided within an integrated housing, Within the integrated housing, the various elements can be interconnected and transmit data therebetween using suitable connection arrangement 1140, for example, an internal bus as known in the art, including the Inter-IC (I2C) bus, wiring, and printed circuit boards.

The system 1000 includes communication interface 1050 that enables communication with other devices via communication channel 1060. The communication interface 1050 can include, but is not limited to, a transceiver configured to transmit and to receive data over communication channel 1060. The communication interface 1050 can include, but is not limited to, a modem or network card and the communication channel 1060 can be implemented, for example, within a wired and/or a wireless medium.

Data is streamed, or otherwise provided, to the system 1000, in various embodiments, using a wireless network such as a Wi-Fi network, for example IEEE 802.11 (IEEE refers to the Institute of Electrical and Electronics Engineers). The Wi-Fi signal of these embodiments is received over the communications channel 1060 and the communications interface 1050 which are adapted for Wi-Fi communications. The communications channel 1060 of these embodiments is typically connected to an access point or router that provides access to external networks including the Internet for allowing streaming applications and other over-the-top communications. Other embodiments provide streamed data to the system 1000 using a set-top box that delivers the data over the HDMI connection of the input block 1130. Still other embodiments provide streamed data to the system 1000 using the RF connection of the input block 1130. As indicated above, various embodiments provide data in a non-streaming manner. Additionally, various embodiments use wireless networks other than Wi-Fi, for example a cellular network or a Bluetooth network.

The system 1000 can provide an output signal to various output devices, including a display 1100, speakers 1110, and other peripheral devices 1120. The display 1100 of various embodiments includes one or more of, for example, a touchscreen display, an organic light-emitting diode (OLED) display, a curved display, and/or a foldable display. The display 1100 can be for a television, a tablet, a laptop, a cell phone (mobile phone), or another device. The display 1100 can also be integrated with other components (for example, as in a smart phone), or separate (for example, an external monitor for a laptop). The other peripheral devices 1120 include, in various examples of embodiments, one or more of a stand-alone digital video disc (or digital versatile disc) (DVR, for both terms), a disk player, a stereo system, and/or a lighting system. Various embodiments use one or more peripheral devices 1120 that provide a function based on the output of the system 1000. For example, a disk player performs the function of playing the output of the system 1000.

In various embodiments, control signals are communicated between the system 1000 and the display 1100, speakers 1110, or other peripheral devices 1120 using signaling such as AV. Link, Consumer Electronics Control (CEC), or other communications protocols that enable device-to-device control with or without user intervention. The output devices can be communicatively coupled to system 1000 via dedicated connections through respective interfaces 1070, 1080, and 1090. Alternatively, the output devices can be connected to system 1000 using the communications channel 1060 via the communications interface 1050. The display 1100 and speakers 1110 can be integrated in a single unit with the other components of system 1000 in an electronic device such as, for example, a television. In various embodiments, the display interface 1070 includes a display driver, such as, for example, a timing controller (T Con) chip.

The display 1100 and speaker 1110 can alternatively be separate from one or more of the other components, for example, if the RF portion of input 1130 is part of a separate set-top box. In various embodiments in which the display 1100 and speakers 1110 are external components, the output signal can be provided via dedicated output connections, including, for example, HDMI ports, USB ports, or COMP outputs.

The embodiments can be carried out by computer software implemented by the processor 1010 or by hardware, or by a combination of hardware and software. As a non-limiting example, the embodiments can be implemented by one or more integrated circuits. The memory 1020 can be of any type appropriate to the technical environment and can be implemented using any appropriate data storage technology, such as optical memory devices, magnetic memory devices, semiconductor-based memory devices, fixed memory, and removable memory, as non-limiting examples. The processor 1010 can be of any type appropriate to the technical environment, and can encompass one or more of microprocessors, general purpose computers, special purpose computers, and processors based on a multi-core architecture, as non-limiting examples.

Various implementations involve decoding. “Decoding”, as used in this application, can encompass all or part of the processes performed, for example, on a received encoded sequence in order to produce a final output suitable for display. In various embodiments, such processes include one or more of the processes typically performed by a decoder, for example, entropy decoding, inverse quantization, inverse transformation, and differential decoding. In various embodiments, such processes also, or alternatively, include processes performed by a decoder of various implementations described in this application.

As further examples, in one embodiment “decoding” refers only to entropy decoding, in another embodiment “decoding” refers only to differential decoding, and in another embodiment “decoding” refers to a combination of entropy decoding and differential decoding. Whether the phrase “decoding process” is intended to refer specifically to a subset of operations or generally to the broader decoding process will be clear based on the context of the specific descriptions and is believed to be well understood by those skilled in the art.

Various implementations involve encoding. In an analogous way to the above discussion about “decoding”, “encoding” as used in this application can encompass all or part of the processes performed, for example, on an input sequence in order to produce an encoded bitstream. In various embodiments, such processes include one or more of the processes typically performed by an encoder, for example, partitioning, differential encoding, transformation, quantization, and entropy encoding. In various embodiments, such processes also, or alternatively, include processes performed by an encoder of various implementations described in this application.

As further examples, in one embodiment “encoding” refers only to entropy encoding, in another embodiment “encoding” refers only to differential encoding, and in another embodiment “encoding” refers to a combination of differential encoding and entropy encoding. Whether the phrase “encoding process” is intended to refer specifically to a subset of operations or generally to the broader encoding process will be clear based on the context of the specific descriptions and is believed to be well understood by those skilled in the art.

Note that the syntax elements as used herein, are descriptive terms. As such, they do not preclude the use of other syntax element names.

When a figure is presented as a flow diagram, it should be understood that it also provides a block diagram of a corresponding apparatus. Similarly, when a figure is presented as a block diagram, it should be understood that it also provides a flow diagram of a corresponding method/process.

Various embodiments refer to parametric models or rate distortion optimization. In particular, during the encoding process, the balance or trade-off between the rate and distortion is usually considered, often given the constraints of computational complexity. It can be measured through a Rate Distortion Optimization (RDO) metric, or through Least Mean Square (LMS), Mean of Absolute Errors (MAE), or other such measurements. The rate distortion optimization is usually formulated as minimizing a rate distortion function, which is a weighted sum of the rate and of the distortion. There are different approaches to solve the rate distortion optimization problem. For example, the approaches may be based on an extensive testing of all encoding options, including all considered modes or coding parameters values, with a complete evaluation of their coding cost and related distortion of the reconstructed signal after coding and decoding. Faster approaches may also be used, to save encoding complexity, in particular with computation of an approximated distortion based on the prediction or the prediction residual signal, not the reconstructed one. Mix of these two approaches can also be used, such as by using an approximated distortion for only some of the possible encoding options, and a complete distortion for other encoding options. Other approaches only evaluate a subset of the possible encoding options. More generally, many approaches employ any of a variety of techniques to perform the optimization, but the optimization is not necessarily a complete evaluation of both the coding cost and related distortion.

The implementations and aspects described herein can be implemented in, for example, a method or a process, an apparatus, a software program, a data stream, or a signal. Even if only discussed in the context of a single form of implementation (for example, discussed only as a method), the implementation of features discussed can also be implemented in other forms (for example, an apparatus or program). An apparatus can be implemented in, for example, appropriate hardware, software, and firmware. The methods can be implemented in, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “one implementation” or “an implementation”, as well as other variations thereof, means that a particular feature, structure, characteristic, and so forth described in connection with the embodiment is included in at least one embodiment. Thus, the appearances of the phrase “in one embodiment” or “in an embodiment” or “in one implementation” or “in an implementation”, as well any other variations, appearing in various places throughout this application are not necessarily all referring to the same embodiment.

Additionally, this application may refer to “determining” various pieces of information. Determining the information can include one or more of, for example, estimating the information, calculating the information, predicting the information, or retrieving the information from memory.

Further, this application may refer to “accessing” various pieces of information. Accessing the information can include one or more of, for example, receiving the information, retrieving the information (for example, from memory), storing the information, moving the information, copying the information, calculating the information, determining the information, predicting the information, or estimating the information.

Additionally, this application may refer to “receiving” various pieces of information. Receiving is, as with “accessing”, intended to be a broad term. Receiving the information can include one or more of, for example, accessing the information, or retrieving the information (for example, from memory). Further, “receiving” is typically involved, in one way or another, during operations such as, for example, storing the information, processing the information, transmitting the information, moving the information, copying the information, erasing the information, calculating the information, determining the information, predicting the information, or estimating the information.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as is clear to one of ordinary skill in this and related arts, for as many items as are listed.

Also, as used herein, the word “signal” refers to, among other things, indicating something to a corresponding decoder. For example, in certain embodiments the encoder signals at least one of a plurality of transforms, coding modes or flags. In this way, in an embodiment the same parameter is used at both the encoder side and the decoder side. Thus, for example, an encoder can transmit (explicit signaling) a particular parameter to the decoder so that the decoder can use the same particular parameter. Conversely, if the decoder already has the particular parameter as well as others, then signaling can be used without transmitting (implicit signaling) to simply allow the decoder to know and select the particular parameter. By avoiding transmission of any actual functions, a bit savings is realized in various embodiments. It is to be appreciated that signaling can be accomplished in a variety of ways. For example, one or more syntax elements, flags, and so forth are used to signal information to a corresponding decoder in various embodiments. While the preceding relates to the verb form of the word “signal”, the word “signal” can also be used herein as a noun.

As will be evident to one of ordinary skill in the art, implementations can produce a variety of signals formatted to carry information that can be, for example, stored or transmitted. The information can include, for example, instructions for performing a method, or data produced by one of the described implementations. For example, a signal can be formatted to carry the bitstream of a described embodiment. Such a signal can be formatted, for example, as an electromagnetic wave (for example, using a radio frequency portion of spectrum) or as a baseband signal. The formatting can include, for example, encoding a data stream and modulating a carrier with the encoded data stream. The information that the signal carries can be, for example, analog or digital information. The signal can be transmitted over a variety of different wired or wireless links, as is known. The signal can be stored on a processor-readable medium.

We describe a number of embodiments. Features of these embodiments can be provided alone or in any combination, across various claim categories and types. Further, embodiments can include one or more of the following features, devices, or aspects, alone or in any combination, across various claim categories and types:
A process or device to perform encoding and decoding with deep neural network compression of a pre-trained deep neural network.
A process or device to perform encoding and decoding of at least one layer of a pre-trained deep neural network, to implement deep neural network compression.
A process or device to perform encoding and decoding with inserted information in a bitstream representative of parameters to implement deep neural network compression of a pre-trained deep neural network comprising one or more layers.
A process or device to perform encoding and decoding with inserted information in a bitstream representative of parameters to implement deep neural network compression of a deep neural network.
A bitstream or signal that includes one or more of the described syntax elements, or variations thereof.
A bitstream or signal that includes syntax conveying information generated according to any of the embodiments described.
Creating and/or transmitting and/or receiving and/or decoding according to any of the embodiments described.
A method, process, apparatus, medium storing instructions, medium storing data, or signal according to any of the embodiments described.
Inserting in the signaling syntax elements that enable the decoder to determine coding mode in a manner corresponding to that used by an encoder.
Creating and/or transmitting and/or receiving and/or decoding a bitstream or signal that includes one or more of the described syntax elements, or variations thereof.
A TV, set-top box, cell phone, tablet, or other electronic device that performs transform method(s) according to any of the embodiments described.
A TV, set-top box, cell phone, tablet, or other electronic device that performs transform method(s) determination according to any of the embodiments described, and that displays (e.g. using a monitor, screen, or other type of display) a resulting image.
A TV, set-top box, cell phone, tablet, or other electronic device that selects, bandlimits, or tunes (e.g. using a tuner) a channel to receive a signal including an encoded image, and performs transform method(s) according to any of the embodiments described.
A TV, set-top box, cell phone, tablet, or other electronic device that receives (e.g. using an antenna) a signal over the air that includes an encoded image, and performs transform method(s).

1-17. (canceled)

18. A method comprising:
obtaining a codebook including a codebook size for quantizing parameters of a tensor associated with at least one layer of a Deep Neural Network, the codebook size obtained according to a distortion value determined between the tensor and a quantized version of the tensor; and
quantizing the parameters of the tensor using the obtained codebook to represent the parameters with at least a determined size.

19. The method of claim 18, further comprising:
encoding the quantized parameters in a bitstream for transmission; and
transmitting the encoded parameters in the bitstream to a decoder.

20. The method of claim 18, further comprising obtaining the codebook size from a binary search over a range of codebook sizes.

21. The method of claim 18, further comprising:
quantizing based on a pdf-based initialization bounded according to a first pdf factor; and
selecting from a candidate bounding pdf factor, the candidate bounding pdf factor based on an entropy obtained from candidate quantized parameters.

22. The method of claim 18, further comprising encoding information representative of a codebook type corresponding to the codebook.

23. An apparatus comprising one or more processors, wherein the one or more processors are configured to:
obtain a codebook including a codebook size for quantizing parameters of a tensor associated with at least one layer of a Deep Neural Network, the codebook size obtained according to a distortion value determined between the tensor and a quantized version of the tensor; and
quantize the parameters of the tensor using the obtained codebook to represent the parameters with at least a determined size.

24. The apparatus of claim 23, wherein the one or more processors are further configured to:
encode the quantized parameters in a bitstream for transmission; and
transmit the encoded parameters in the bitstream to a decoder.

25. The apparatus of claim 23, wherein the one or more processors are further configured to obtain the codebook size from a binary search over a range of codebook sizes.

26. The apparatus of claim 23, wherein the one or more processors are further configured to:
quantize based on a pdf-based initialization bounded according to a first pdf factor; and
select from a candidate bounding pdf factor, the candidate bounding pdf factor based on an entropy obtained from candidate quantized parameters.

27. The apparatus of claim 23, wherein the one or more processors are further configured to encode information representative of a codebook type corresponding to the codebook.

28. A method comprising:
receiving an encoded bitstream, wherein the encoded bitstream comprises quantized parameters of a tensor associated with at least one layer of a Deep Neural Network, and wherein the encoded bitstream comprises a codebook including a codebook size obtained according to a distortion value determined between the tensor and a quantized version of the tensor;
decoding the codebook from the bitstream; and
performing inverse quantization of the parameters of the tensor using the codebook.

29. The method of claim 28, further comprising:
parsing input bins to extract quantized parameters.

30. The method of claim 29, further comprising:
inversely quantizing the quantized parameters to derive a final parameter value; and
inversely transforming the final parameter value.

31. The method of claim 28, further comprising:
dequantizing based on a pdf-based initialization bounded according to a first pdf factor.

32. The method of claim 28, further comprising:
decoding information representative of a codebook type corresponding to the codebook.

33. An apparatus comprising one or more processors, wherein the one or more processors are configured to:
receive an encoded bitstream, wherein the encoded bitstream comprises quantized parameters of a tensor associated with at least one layer of a Deep Neural Network, and wherein the encoded bitstream comprises a codebook including a codebook size obtained according to a distortion value determined between the tensor and a quantized version of the tensor; decode the codebook from the bitstream; and
perform inverse quantization of the parameters of the tensor using the codebook.

34. The apparatus of claim 33, wherein the one or more processors are further configured to parse input bins to extract quantized parameters.

35. The apparatus of claim 34, wherein the one or more processors are further configured to inversely quantize the quantized parameters to derive a final parameter value; and inversely transform the final parameter value.

36. The apparatus of claim 33, wherein the one or more processors are further configured to dequantize based on a pdf-based initialization bounded according to a first pdf factor.

37. The apparatus of claim 33, wherein the one or more processors are further configured to decode information representative of a codebook type corresponding to the codebook.
